(19) United States
(12) Patent Application Publication
(10) Pub. No.: US 2013/0154740 A1
(43) Pub. Date: Jun. 20, 2013

(54) TECHNIQUES FOR PGA LINEARITY

(71) Applicant: Weijun Serena Xie, San Diego, CA (US)

(72) Inventor: Weijun Serena Xie, San Diego, CA (US)

(73) Assignee: QUALCOMM INCORPORATED, San Diego, CA (US)

(21) Appl. No.: 13/421,440

(22) Filed: Mar. 15, 2012

Related U.S. Application Data
(60) Provisional application No. 61/576,859, filed on Dec. 16, 2011.

(51) Int. Cl. H03F 3/45

(52) U.S. Cl. 330/260

(57) ABSTRACT

Techniques for designing a highly linear programmable gain amplifier (PGA). In an aspect, the PGA includes a plurality of feedback switches selectively coupling an output of an operational amplifier (op amp) to an input of the op amp via a corresponding series-coupled feedback resistance. The PGA may further include a plurality of input switches selectively coupling an input of the op amp to a PGA input voltage via a corresponding series-coupled input resistance. The switches are designed such that the ratio of on-resistances between any two switches is substantially equal to the ratio of the corresponding series-coupled resistances. In an exemplary embodiment, transistors implementing the switches may be accordingly sized to implement the desired on-resistance ratios.

### CLAIM OF PRIORITY UNDER 35 U.S.C. §119

The present application for Patent claims priority to Provisional Application No. 61/576,859, entitled “Techniques for PGA linearity” filed Dec. 16, 2011, and assigned to the assignee hereof and hereby expressly incorporated by reference herein.

### BACKGROUND

1. Field

The disclosure relates to programmable gain amplifiers (PGA's), and in particular, to techniques for improving the linearity of PGA's.

2. Background

A programmable gain amplifier (PGA) is used to provide a digitally programmable gain to an input voltage, either single-ended or differential. PGA's are commonly designed by configuring an operational amplifier (op amp) to have input and/or feedback resistive networks with programmable resistance. To implement the programmable resistance, any of the resistive networks may include a plurality of parallel-coupled resistors. Each of the resistors may be coupled in series with a switch, such that selectively closing or opening the switch allows the corresponding series-coupled resistor to be switched in or out of the resistive network.

The aforementioned switches may be implemented as MOS transistors, i.e., as MOS switches. The on-resistance of such MOS switches may vary as a function of their terminal voltages, e.g., gate-to-source voltages, and the source voltages may vary over a wide range. It will be appreciated that the varying on-resistance of MOS switches may affect the accuracy of the resistive networks, and can thus be a dominant cause of poor PGA linearity. To improve PGA linearity, larger MOS switch sizes may be used. However, this may undesirably increase integrated circuit chip size.

It would be desirable to provide simple and area-efficient techniques to improve the linearity of PGA's utilizing switchable resistive networks.

### BRIEF DESCRIPTION OF THE DRAWINGS

FIG. 1 illustrates a prior art implementation of a programmable gain amplifier (PGA).

FIG. 2 illustrates an exemplary embodiment of a PGA having improved linearity.

FIG. 3 illustrates an exemplary embodiment of the present disclosure, wherein an op amp has a differential input and a single-ended output.

FIG. 4 illustrates an exemplary embodiment of a method according to the present disclosure.

FIG. 5 shows an exemplary embodiment of a PGA having a differential input and single-ended output, to which the techniques of the present disclosure may also be applied.

### DETAILED DESCRIPTION

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The detailed description set forth below in connection with the appended drawings is intended as a description of exemplary aspects of the invention and is not intended to represent the only exemplary aspects in which the invention can be practiced. The term “exemplary” used throughout this description means “serving as an example, instance, or illustration,” and should not necessarily be construed as preferred or advantageous over other exemplary aspects. The detailed description includes specific details for the purpose of providing a thorough understanding of the exemplary aspects of the invention. It will be apparent to those skilled in the art that the exemplary aspects of the invention may be practiced without these specific details. In some instances, well-known structures and devices are shown in block diagram form in order to avoid obscuring the novelty of the exemplary aspects presented herein.

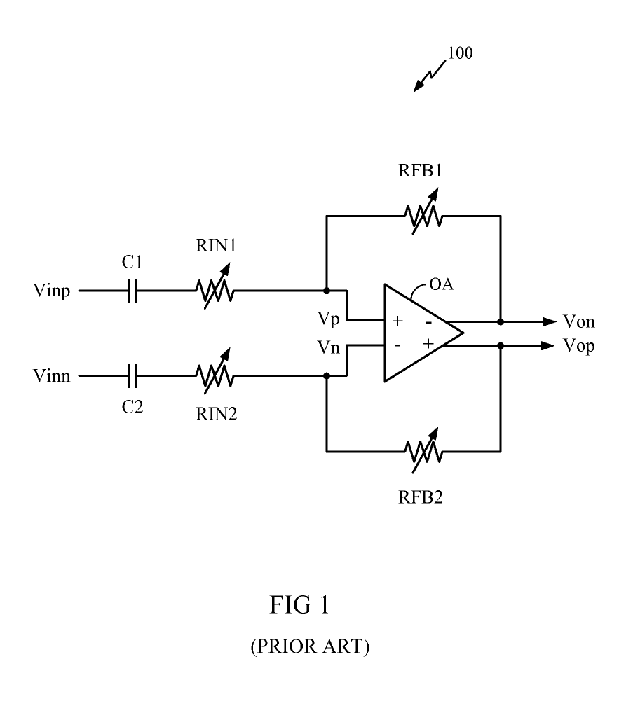

FIG. 1 illustrates a prior art implementation 100 of a programmable gain amplifier (PGA). Referring to FIG. 1, a fully differential op amp (OA) amplifies the difference between positive (+) and negative (−) op amp input voltages Vp, Vn at positive and negative input terminals to generate a differential (+, −) output voltage Vop, Von at positive and negative output terminals. The op amp is further configured with negative feedback using variable feedback resistances RFB1 and RFB2 and variable input resistances RIN1 and RIN2. RIN1 and RIN2 are in turn coupled to PGA input voltages Vinp and Vinn, respectively, via coupling capacitors C1 and C2, respectively. It will be appreciated that in alternative exemplary embodiments (not shown), the coupling capacitors C1 and C2 may be omitted, and any of the variable input resistances and variable feedback resistances may instead be configured to have a fixed resistance.

From FIG. 1, one of ordinary skill in the art may derive the following equation relating the input and output voltages in the system:

$$\frac{Vop - Von}{Vinp - Vinn} = \frac{R F B}{R I N} ; \qquad ( Equation 1 )$$

assuming RFB1=RFB2=RFB, and RIN1=RIN2=RIN. By setting the ratio RFB/RIN, the gain from the differential PGA input voltage (Vinp−Vinn) to the differential output voltage (Vop−Von) may be made programmable.

In practical implementations, it will be appreciated that various factors may cause the actual gain of the PGA 100 to deviate from the ideal gain as expected from Equation 1. For example, each of the variable resistances RFB1, RFB2, RIN1, and RIN2 may be implemented as a parallel bank of switchable resistors, i.e., wherein each resistor is coupled in series with a switch, and a plurality of such series-coupled resistors and switches are in turn coupled with each other in parallel. It will be appreciated that all switches have some finite on-resistance when closed. Furthermore, if a switch is implemented, e.g., as a MOS transistor, then the finite on-resistance may itself be variable depending on the terminal voltages of the transistors, e.g., the gate-to-source voltage across each transistor switch. This may cause the resistances RFB and RIN to vary depending on the input and output voltages, undesirably contributing to PGA non-linearity.

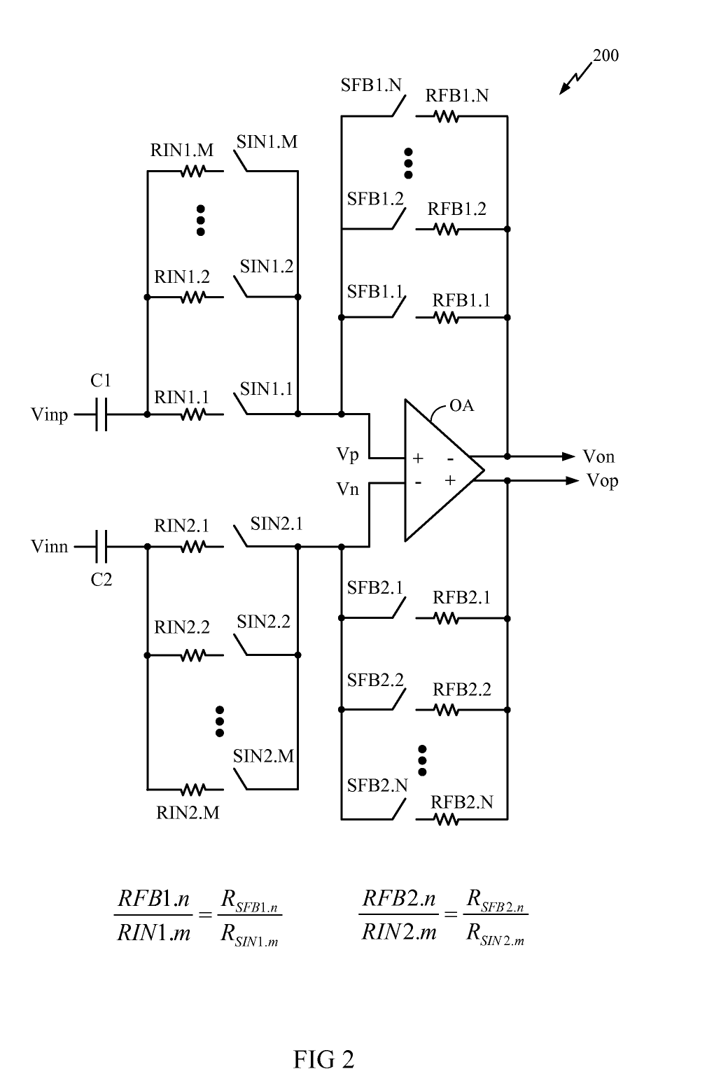

FIG. 2 illustrates an exemplary embodiment 200 of a PGA designed to address these issues. In FIG. 2, each of the resistances RFB1, RFB2, RIN1, and RIN2 of FIG. 1 is shown implemented as a parallel bank of switchable resistances, as earlier described hereinabove. For example, the feedback resistance RFB1 includes a parallel bank of switchable resistors, i.e., RFB1.1 coupled in series with a switch SFB1.1, RFB1.2 coupled in series with SFB1.2, etc., up to RFB1.N coupled in series with SFB1.N, wherein N represents the total number of parallel resistances in RFB1. Note the exemplary embodiment 200 is shown for illustrative purposes only, and is not meant to restrict the scope of the present disclosure to a particular implementation wherein all resistive networks are implemented as shown in FIG. 2.

By controlling which of the switches are open and closed, the resistance of the corresponding resistive network may be controlled, and thus the gain of the PGA 200 may be programmed Note the individual resistors may be sized according to any scheme known in the art, e.g., a binary-weighted scheme, uniformly weighted scheme, etc.

In FIG. 2, it will be appreciated that each of the switches shown has one terminal directly coupled to either Vp or Vn of the op amp (OA). For example, switches SIN1.1 through SIN1.M (wherein M represents the total number of parallel resistances in SIN1) and SFB1.1 through SFB1.N all have one terminal directly coupled to Vp of the OA, while switches SIN2.1 through SIN2.M and SFB2.1 through SFB2.N all have one terminal directly coupled to Vn of the OA, etc. It will be appreciated that this feature is particularly advantageous in certain cases wherein Vp and Vn of the OA are not expected to vary much, e.g., when the input voltages Vinp and Viin are fully differential with respect to a common-mode voltage reference VCM, and thus Vp and Vn are both expected to remain relatively close to VCM even as Vinp and Vinn vary. This may help reduce the variation of terminal voltages (e.g., gate-to-source voltages) across any individual transistor switch, which may in turn reduce the non-linearities in the circuit 200.

In an aspect of the present disclosure, the on-resistance of each individual switch may further be designed to improve the linearity of the PGA 200. According to an exemplary embodiment, the feedback switch SFB and input switch SIN may be designed such that the ratio of their on-resistances to each other is configured to be substantially equal to the ratio between the feedback resistance RFB and the input resistance RIN. Correspondingly, the same design technique may be applied to the individual constituent switches and resistances making up each of SFB, SIN, RFB, and RIN, if such switch and/or resistance is made up of a parallel bank of switchable resistors as earlier described hereinabove.

In particular, referring again to FIG. 2, let n denote an arbitrary index from 1 to N, and m denote an arbitrary index from 1 to M. According to the exemplary embodiment, the on-resistance of each individual switch in FIG. 2 may be chosen according to the following equations, as also highlighted in FIG. 2:

$$\begin{matrix}\frac{R F B 1 \cdot n}{R I N 1 \cdot m} = \frac{{R}_{SFB 1 \cdot n}}{{R}_{SIN 1 \cdot m}} ; & ( Equation 2 a ) \\ \frac{R F B 2 \cdot n}{R I N 2 \cdot m} = \frac{{R}_{SFB 2 \cdot n}}{{R}_{SIN 2 \cdot m}} ; \\ and & ( Equation 2 b ) \\ \frac{R F B}{R I N} = \frac{{R}_{SFB}}{{R}_{SIN}} ; & ( Equation 2 c )\end{matrix}$$

wherein R_{SFB1.n}, R_{SIN.m}, R_{SFB2.n}, and R_{SIN2.m}, represent the on-resistances of the corresponding switches, and Equation 2c is a simplified equation representing the total composite resistance of each element. If the switch on-resistances are chosen according to Equations 2a and 2b, then it will be appreciated that the PGA gain equation may correspondingly be expressed as follows:

$$\begin{matrix}\frac{Vop - Von}{Vinp - Vinn} = \frac{R F B + {R}_{SFB}}{R I N + {R}_{SIN}} ; \\ = \frac{R F B}{R I N} ( \frac{1 + {R}_{SFB} / RFB}{1 + {R}_{SIN} / R I N} ) ; ( Equation 3 b ) \\ = \frac{R F B}{R I N} ; ( Equation 3 c )\end{matrix} \qquad ( Equation 3 a )$$

wherein the last step follows directly from Equation 2c. Note the relationships indicated in the equations above are intended to be approximate and/or nominal only, as the actual resistances may vary depending on other auxiliary factors, e.g., drain-to-source voltage drops across each transistor switch, temperature, etc.

In light of the above observations, one of ordinary skill in the art will appreciate that by designing the switches in the PGA 200 to have on-resistances according to Equations 2a and 2b, the switches' effect on the overall gain of the PGA 200 may be nominally cancelled, and performance may be thereby improved.

It will be appreciated that during operation of the PGA, the voltage drops (e.g., gate-to source voltages) across each switch may be changing over time, e.g., due to variations in the input and output voltages, and thus the individual on-resistances may be similarly changing over time. To design the on-resistance of switches to have the desired ratios as described above over variations in input and output voltages, the sizes of the transistors implementing the switches may be chosen accordingly. In particular, lower on-resistance generally corresponds to larger transistor width (given the same length), while higher on-resistance corresponds to smaller transistor width. In light of this observation, the design criteria described in Equations 2a through 2c may be implemented by, e.g., inversely proportionally sizing the widths of the transistors used to implement such switches.

In particular, the transistor switch sizes may be chosen as follows:

$$\begin{matrix}\frac{R F B 1 \cdot n}{R I N 1 \cdot m} = \frac{{( W / L )}_{SIN 1 \cdot m}}{{( W / L )}_{SFB 1 \cdot n}} ; \\ and & ( Equation 4 a ) \\ \frac{R F B 2 \cdot n}{R I N 2 \cdot m} = \frac{{( W / L )}_{SIN 2 \cdot m}}{{( W / L )}_{SFB 2 \cdot n}} ; & ( Equation 4 b )\end{matrix}$$

wherein (W/L)_{SFB1.n}, (W/L)_{SIN.m}, (W/L)_{SFB2.n}, and (W/L)_{SIN.m}, represent the width-to-length ratios (also referred to herein as the “sizes”) of the corresponding transistor switches. It will be appreciated that if the transistor sizes are chosen according to Equations 4a-4b, then the ratios called for in Equations 2a-2c may be approximately maintained regardless of the possible changes in instantaneous on-resistance due to changing voltage drops across the transistors.

Note the techniques described hereinabove may be readily applied to exemplary embodiments wherein the PGA input voltages Vinp and Vinn are fully differential with respect to each other, and also to single-ended input embodiments wherein, e.g., Vinp contains the signal of interest, while Vinn is tied to a fixed reference, e.g., ground.

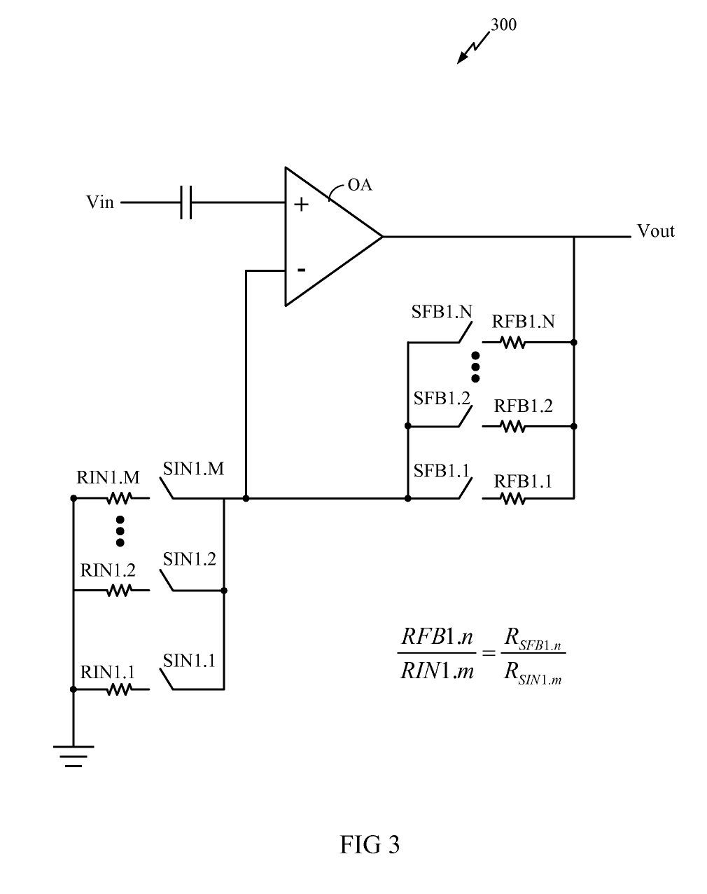

While an op amp having fully differential input and differential output has been shown and described hereinabove, one of ordinary skill in the art will readily appreciate that the aforementioned techniques may also be applied to an op amp having a differential input and a single-ended output. FIG. 3 illustrates an exemplary embodiment 300 of the present disclosure, wherein the OA has a differential input and a single-ended output, and the PGA has a single-ended input and single-ended output. In FIG. 3, a feedback path including a plurality of parallel-coupled switchable resistors RFB1.1 through RFB1.N couples the OA output Vout to the OA negative input. The OA negative input is further coupled to ground through a plurality of parallel coupled switchable resistors RIN1.1 through RIN1.M. While the PGA 300 has different gain equations from the PGA 200 shown in FIG. 2, one of ordinary skill in the art will appreciate that similar techniques as disclosed hereinabove with reference to FIG. 2 to proportionally set the on-resistances of the switches may be readily applied to the exemplary embodiment of FIG. 3 as well. Such alternative exemplary embodiments are contemplated to be within the scope of the present disclosure.

Note while techniques have been described hereinabove with reference to both the input and feedback resistances being simultaneously variable, it will be appreciated that alternative exemplary embodiments are readily derivable by one of ordinary skill in the art. For example, in an alternative exemplary embodiment, only one of the input resistance or the feedback resistance may be made variable to select the gain of the PGA. In this case, the techniques of the present disclosure may still be incorporated, e.g., the switches of either the input or feedback resistive network may be directly coupled to an input terminal of the op amp, and the individual switch on-resistances may be set in proportion to the ratio between the corresponding variable resistance and a portion of the non-programmable resistance. In either case, a “dummy” switch, e.g., a transistor switch that is configured to be always conducting, may be utilized for the network having fixed resistance.

For example, suppose an input resistance includes a single non-programmable (fixed) resistance of 110 Ohms. Such an input resistance may be implemented as a 100-Ohm input resistance coupled with an always-conducting (for example, with a transistor having a fixed always-on gate voltage) 10-Ohm input transistor “dummy” switch. Note the 10-Ohm on-resistance of the transistor dummy switch may be nominal only, as the actual on-resistance of the transistor dummy switch may vary depending on the gate-to-source voltage drops across the switch. Furthermore, a first branch of a parallel resistive feedback network may be a 100-Ohm feedback resistance coupled in series with a switch having a 10-Ohm on-resistance, a second branch of the parallel network may be a 200-Ohm feedback resistance coupled in series with a switch having a 20-Ohm on-resistance, etc. Note the sizes of transistors implementing the switches may be chosen according to the principles described hereinabove, e.g., if a first transistor switch has twice the on-resistance of a second transistor switch, then the first transistor switch may be have half the size of the second transistor switch. Such exemplary embodiments are contemplated to be within the scope of the present disclosure.

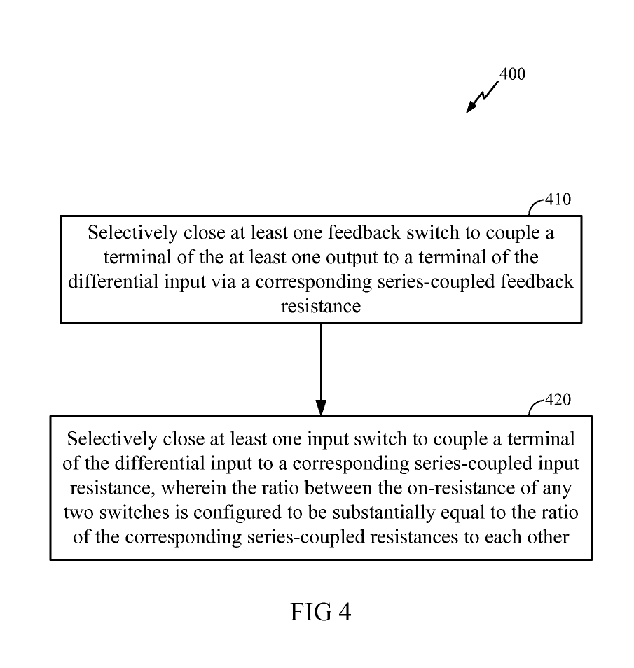

FIG. 4 illustrates an exemplary embodiment of a method according to the present disclosure. Note FIG. 4 is shown for illustrative purposes only, and is not meant to limit the scope of the present disclosure to any particular exemplary embodiment shown.

In FIG. 4, at block 410, at least one feedback switch is selectively closed to couple a terminal of the at least one output to a terminal of the differential input via a corresponding series-coupled feedback resistance.

At block 420, at least one input switch is selectively closed to couple a terminal of the differential input to a corresponding series-coupled input resistance. In an exemplary embodiment, the ratio between the on-resistances of any two switches is substantially equal to the ratio of the corresponding series-coupled resistances to each other.

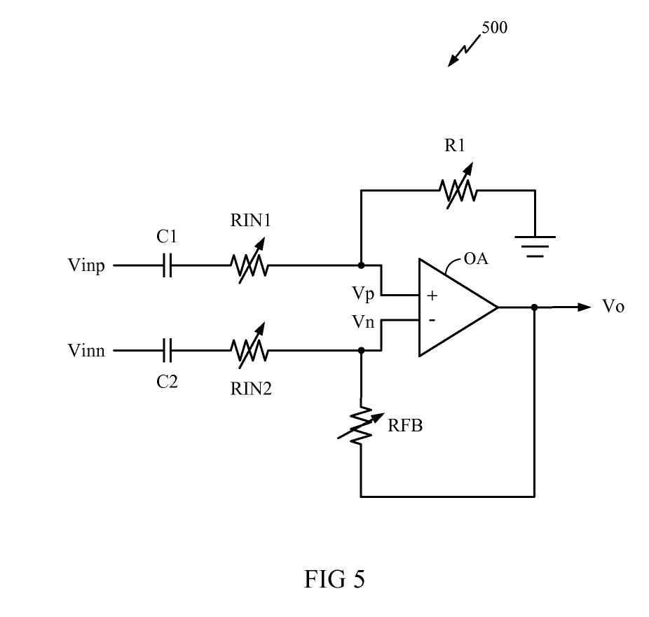

FIG. 5 shows an exemplary embodiment 500 of a programmable gain amplifier having a differential input and single-ended output, to which the techniques of the present disclosure may also be applied. In FIG. 5, a variable resistance RFB couples the negative input Vn of the OA to the output Vo. Furthermore, a variable resistance R1 couples the positive input Vp of the OA to ground. One of ordinary skill the art will appreciate that the techniques of the present disclosure, for example, proportional sizing of switches (not shown in FIG. 5) may be readily applied to the PGA 500, and such exemplary embodiments are contemplated to be within the scope of the present disclosure.

In this specification and in the claims, it will be understood that when an element is referred to as being “connected to” or “coupled to” another element, it can be directly connected or coupled to the other element or intervening elements may be present. In contrast, when an element is referred to as being “directly connected to” or “directly coupled to” another element, there are no intervening elements present. Furthermore, when an element is referred to as being “electrically coupled” to another element, it denotes that a path of low resistance is present between such elements, while when an element is referred to as being simply “coupled” to another element, there may or may not be a path of low resistance between such elements.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill in the art would further appreciate that the various illustrative logical blocks, modules, circuits, and algorithm steps described in connection with the exemplary aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the exemplary aspects of the invention.

The various illustrative logical blocks, modules, and circuits described in connection with the exemplary aspects disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the exemplary aspects disclosed herein may be embodied directly in hardware, in a software module executed by a processor, or in a combination of the two. A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-Ray disc where disks usually reproduce data magnetically, while discs reproduce data optically with lasers. Combinations of the above should also be included within the scope of computer-readable media.

The previous description of the disclosed exemplary aspects is provided to enable any person skilled in the art to make or use the invention. Various modifications to these exemplary aspects will be readily apparent to those skilled in the art, and the generic principles defined herein may be applied to other exemplary aspects without departing from the spirit or scope of the invention. Thus, the present disclosure is not intended to be limited to the exemplary aspects shown herein but is to be accorded the widest scope consistent with the principles and novel features disclosed herein.

1. An apparatus comprising:
an amplifier having differential input terminals and at least one output;
at least one feedback resistance coupled in series with a corresponding feedback switch, each feedback resistance and corresponding feedback switch coupling a terminal of the at least one output to a differential input terminal; and
at least one input resistance coupled in series with a corresponding input switch, each input switch coupling a terminal of the differential input to a corresponding input resistance;
wherein the ratio between the on-resistances of any two switches is configured to be substantially equal to the ratio of the corresponding series-coupled resistances to each other.

2. The apparatus of claim 1, the at least one feedback resistance comprising first and second feedback resistances, wherein the ratio between the on-resistances of the feedback switches coupled to the first and second feedback resistances is substantially equal to the ratio between the first and second feedback resistances.

3. The apparatus of claim 1, the at least one feedback resistance comprising a plurality of feedback resistances, the at least one input resistance comprising a single input resistance, wherein the ratio of the on-resistance of each feedback switch to the on-resistance of the input switch is substantially equal to the ratio of the corresponding feedback resistance to the single input resistance.

4. The apparatus of claim 1, each switch comprising an MOS transistor.

5. The apparatus of claim 4, each switch comprising an MOS transistor with a width-to-length ratio set in inverse proportion to the corresponding series-coupled resistance.

6. The apparatus of claim 1, at least one of the at least one input resistance and the at least one feedback resistance comprising a dummy switch that is always closed.

7. The apparatus of claim 1, the at least one output comprising a single-ended output terminal, each feedback switch electrically coupling the single-ended output terminal to the negative input terminal via a corresponding feedback resistance when said feedback switch is selectively closed, and each input switch coupling the negative input terminal to a corresponding input resistance, each of the at least one input resistance further coupled to a ground voltage.

8. The apparatus of claim 1, the at least one output comprising positive and negative output terminals, a first plurality of feedback switches each coupling the negative output terminal to the positive input terminal via corresponding feedback resistances when said first plurality of feedback switches are selectively closed, a second plurality of feedback switches each coupling the positive output terminal to the negative input terminal via corresponding feedback resistances when said second plurality of feedback switches are selectively closed.

9. The apparatus of claim 1, wherein the positive and negative input terminals are coupled to PGA (programmable gain amplifier) input voltages that are fully differential with respect to a common reference voltage.

10. The apparatus of claim 1, each of the at least one feedback switch being disposed between the corresponding feedback resistance and said terminal of the differential input.

11. The apparatus of claim 1, each feedback switch electrically coupling a terminal of the differential input to a terminal of the corresponding feedback resistance when said feedback switch is closed, each feedback resistance further coupled to a terminal of the at least one output.

12. The apparatus of claim 1, each switch comprising an MOS transistor switch, wherein the ratio between the width-divided-by-length (W/L) of any two MOS transistor switches is substantially equal to the ratio of the corresponding series-coupled resistances to each other.

13. A method for configuring an amplifier, the amplifier having differential input terminals and at least one output, the method comprising:
selectively closing at least one feedback switch to couple a terminal of the at least one output to a terminal of the differential input via a corresponding series-coupled feedback resistance, a terminal of each feedback switch directly coupled to the terminal of the differential input; and
selectively closing at least one input switch to couple a terminal of the differential input to a corresponding series-coupled input resistance, a terminal of each input switch directly coupled to the terminal of the differential input;
wherein the ratio between the on-resistances of any two switches is configured to be substantially equal to the ratio of the corresponding series-coupled resistances to each other.

14. The method of claim 13, each switch comprising an MOS transistor with a width-to-length ratio set in inverse proportion to the corresponding resistance.

15. The method of claim 13, the at least one output comprising positive and negative output terminals, the method further comprising:
selectively closing a first plurality of feedback switches to couple the negative output terminal to the positive input terminal via a corresponding feedback resistance; and
selectively closing a second plurality of feedback switches to couple the positive output terminal to the negative input terminal via a corresponding feedback resistance.

16. The method of claim 13, at least one of the at least one input resistance and the at least one feedback resistance comprising a dummy switch that is always closed.

17. The method of claim 13, the at least one feedback resistance comprising first and second feedback resistances, wherein the ratio between the on-resistances of the feedback switches coupled to the first and second feedback resistances is substantially equal to the ratio between the first and second feedback resistances.

18. An apparatus comprising:
an amplifier having at least one output and a differential input comprising positive and negative input terminals;
means for coupling a terminal of the at least one output to a terminal of the differential input via a corresponding series-coupled feedback resistance; and
means for coupling a terminal of the differential input to a corresponding series-coupled input resistance;
wherein each of said means is configured to have an on-resistance at a fixed proportion relative to the corresponding series-coupled resistance.

19. The apparatus of claim 18, the means for coupling a terminal of the at least one output to a terminal of the differential input comprising at least one feedback resistance coupled in series with a corresponding feedback switch, each feedback switch coupling a terminal of the at least one output to a terminal of the differential input via a corresponding feedback resistance when said feedback switch is selectively closed.

20. The apparatus of claim 18, the means for coupling a terminal of the differential input to a corresponding series-coupled input resistance comprising at least one input resistance coupled in series with a corresponding input switch, each input switch coupling a terminal of the differential input to a corresponding input resistance, wherein the ratio of the on-resistances of any two switches is set to be substantially equal to the ratio of the corresponding series-coupled resistances to each other.
